(19) United States
(12) Patent Application Publication
(10) Pub. No.: US 2010/0139561 A1
(43) Pub. Date: Jun. 10, 2010

(54) Counter sunk screen

(76) Inventor: Terry R. Bloom, Middlebury, IN (US)

Correspondence Address: Daniel J. Deneufbourg, Esq.;CTS Corporation, 171 Covington Drive, Bloomingdale, IL, 60108, US

(21) Appl. No.: 12/653,042

(22) Filed: Dec. 8, 2009

Related U.S. Application Data
(60) Provisional application No. 61/201,402, filed on Dec. 10, 2008.

(51) Int. Cl. H01L 21/461

(52) U.S. Cl. 118/504; 257/E21.483

(57) ABSTRACT

A printing screen which, in one embodiment, is adapted to print resistors on a substrate including conductors. An emulsion material covers at least a first area of the screen and at least a second area of the screen defines a region of the screen through which a thick film paste material passes and is deposited onto the substrate to form the resistors. A pattern of recesses, defined in the bottom surface of the layer of emulsion material, matches the pattern of conductors on the substrate. When the screen is lowered onto or near the substrate, the conductors are fitted into the respective recesses to assure that during printing the screen lays flat against the substrate irrespective of the number, size, or location of the conductors on the substrate for forming resistors of uniform thickness and thus uniform resistance.

### CROSS-REFERENCE TO RELATED APPLICATION

This application claims the benefit of the filing date and disclosure of U.S. Provisional Application Ser. No. 61/201,402 filed on Dec. 10, 2008 which is explicitly incorporated herein by reference as are all references cited therein.

### TECHNICAL FIELD

This invention relates to screen printing and, more specifically, to a screen assembly for printing thick film electronic elements such as, for example, resistors on a substrate or the like.

### BACKGROUND OF THE INVENTION

Current screen printing methods use a screen assembly 100 as shown in FIGS. 1-4 comprised of a wire mesh screen 102 which has been stretched over a support frame 101 and includes a mask thereon comprised of closed portions or areas of wire mesh material which have been covered with a resin such as, for example, a photosensitive emulsion film 103 and open portions or areas of wire mesh material which are not covered with the photosensitive emulsion film. The screen 102 is manufactured in a manner in which the photosensitive emulsion film initially covers the full surface of the wire mesh material and a photolithographic process is used to remove selected portions or areas of the photosensitive film to create the open portions or areas in the wire mesh material.

A squeegee 104 as shown in FIGS. 2 and 3 is used and wiped over the top surface of the screen 102 and the mask formed thereon to spread and extrude a thick film material or paste 106 downwardly through only the open portions or areas of the mask and wire mesh material and then onto the surface of a substrate or board 300 or the like on which the screen assembly 100 is seated.

Screen printing is used in a variety of applications including the printing of resistors or the like thick film electronic elements onto the top surface of substrate or board 300. Resistors such as, for example, the resistor 108 shown in FIGS. 3 and 4, must oftentimes be formed on and cover both the surface of raised elements such as conductors 304 and 306 or the like which has been previously formed or placed on the surface of substrate 300, and the region of the substrate surface surrounding the conductors 304 and 306.

In view that it is desirable to seat the screen 102 as flat and horizontal as possible against the surface of the substrate 300 and conductors 304 and 306 to form resistors of uniform thickness, the current method requires the application of squeegee pressures in the order of about thirty (30) pounds to deform and stretch the screen 102 over the conductors 304 and 306. However, as shown in FIGS. 2-4, the deformation and stretching of screen 102 does not completely flatten the screen 102 against the substrate 300 and can result in the formation of resistors 108 of non-uniform thickness and thus non-uniform resistance as exhibited in the graph of FIG. 9. The excess squeegee pressures also contribute to the increased and premature wear of the squeegee and screen material and thus the need to replace squeegees and screens during production runs.

There thus remains a continued need for a screen assembly for printing resistors or the like electronic/electrical elements on a substrate in which the screen can be laid flat against the surface of the substrate during printing notwithstanding the presence of conductors or the like raised electronic/electrical elements on the substrate to assure the formation of resistors of uniform thickness and thus uniform resistance.

### SUMMARY OF THE INVENTION

The present invention is directed broadly to a screen assembly for forming one or more resistors or the like on the surface of a substrate in which the screen includes a bottom surface defining a pattern of counter sinks or recesses or cavities which allow the screen to lay flat against the surface of the substrate during printing notwithstanding the presence of a pattern of one or more raised elements such as conductors on the surface of the substrate.

In one embodiment, the screen assembly comprises a screen which defines a plurality of openings, at least a first area of the screen which is covered with a layer of material which blocks the plurality of openings and includes a top surface and a bottom surface, at least a second area of the screen which allows a resistor forming paste to pass through the plurality of openings for printing one or more resistors on the substrate, and one or more recesses which are defined in the bottom surface of the layer of material covering the first area of the screen whereby during printing the one or more conductors on the surface of the substrate are fitted in the respective one or more recesses.

This feature allows the screen to lay flat against the surface of the substrate during printing to assure the formation of resistors of uniform thickness and thus uniform resistance.

There are other advantages and features of this invention, which will be more readily apparent from the following detailed description of the embodiment of the invention, the drawings, and the appended claims.

### BRIEF DESCRIPTION OF THE FIGURES

In the accompanying drawings that form part of the specification, and in which like numerals are employed to designate like parts throughout the same:

FIGS. 1-4 are simplified vertical cross-sectional views of a printing screen assembly and the process currently in use for printing one or more resistors or the like electronic/electrical elements on the surface of a substrate including one or more raised electronic/electrical elements such as, for example, conductors previously applied or formed thereon;

FIG. 5A is a simplified vertical cross-sectional view of a printing screen assembly in accordance with the present invention for printing one or more resistors or the like thick film electronic/electrical elements on the surface of a substrate including a pattern of one or more raised electronic/electrical elements such as, for example, conductors previously applied or formed thereon;

FIG. 5B is a simplified bottom plan view of the screen assembly of FIG. 5A;

FIG. 6 is a simplified vertical cross-sectional view depicting the screen assembly of FIGS. 5A and 5B positioned flat against the surface of the substrate with a squeegee shown therein in its position prior to application of a thick film resistor forming paste to the surface of the substrate;

FIG. 7 is a simplified vertical cross-sectional view depicting the screen assembly of FIGS. 5A and 5B positioned flat against the surface of the substrate following the squeegee's application of the thick film resistor forming paste to the surface of the substrate;

FIG. 8 is simplified vertical cross-sectional view depicting the thick film resistor which has been formed on the surface of the substrate using the screen assembly of the present invention;

FIG. 9 is a graph of resistor resistance versus time for a resistor made with the screen assembly shown in FIGS. 1-4; and

FIG. 10 is a graph of resistor resistance versus time for a resistor made with the screen assembly of the present invention.

### DETAILED DESCRIPTION OF THE EMBODIMENT

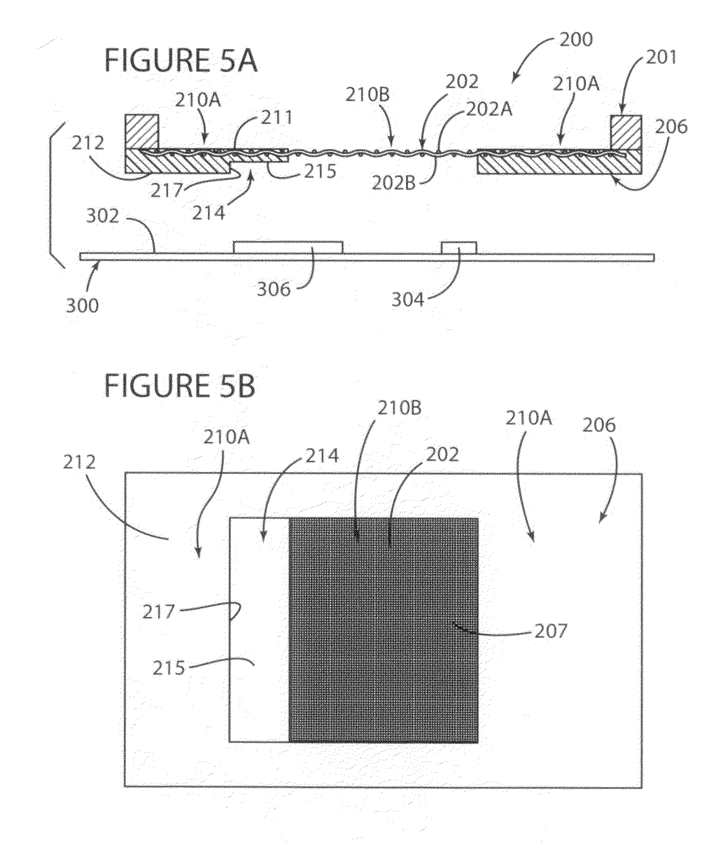

A counter-sunk screen assembly 200 in accordance with the present invention is shown in simplified form in FIGS. 5-8. Screen assembly 200 comprises a frame 201 which may be made of any suitable rigid material and a screen 202 that is strung or stretched across the frame 201 and may be made from any suitable material including a woven wire mesh comprised of first and second respective series of parallel wires 202A and 202B (FIG. 5A) which have been positioned in a normal relationship to each other and interwoven and cross-stitched together in an under and over relationship which defines and creates a plurality of openings 207 (FIG. 5B) in the screen 202.

A layer of suitable photosensitive emulsion film or material 206, such as a resin or the like, is applied to the screen 202 during the manufacture of the screen assembly 200 and defines a screen printing mask pattern thereon including one or more first negative closed mask pattern areas or regions 210A in which the openings 207 in screen 202 are covered or closed with the emulsion material 206 and one or more second positive open mask pattern areas or regions 210B in which the openings 207 in screen 202 have been left open or emulsion-free (i.e., not covered with emulsion material 206). The length and width of mask pattern area 210B matches and corresponds to the length and width of the resistor(s) 400 (FIG. 8) to be formed on the substrate 300 as described in more detail below. In the embodiment shown, the layer of emulsion material 206 is about 0.5 mils (0.0005 inches) in thickness and includes a top surface 211 and a bottom surface 212.

According to the invention, an elongated recess or counter sink or cavity 214 is defined in a portion of the layer of emulsion material 206 which forms one of the first closed regions or areas 210A of screen 202. Specifically, in the embodiment shown, recess 214 is defined by a portion of the lower surface 212 of the layer of emulsion material 206 from which emulsion material is absent or has been removed or etched away. In the embodiment shown, recess 214 is located adjacent to and is contiguous with the left side edge of the second positive mask pattern region or area 210A and includes a recessed horizontal surface 215 which is parallel to and spaced from the horizontal surface 212 of emulsion layer 206 and a vertical surface 217 extending between, and generally normal to, the respective horizontal surfaces 212 and 215.

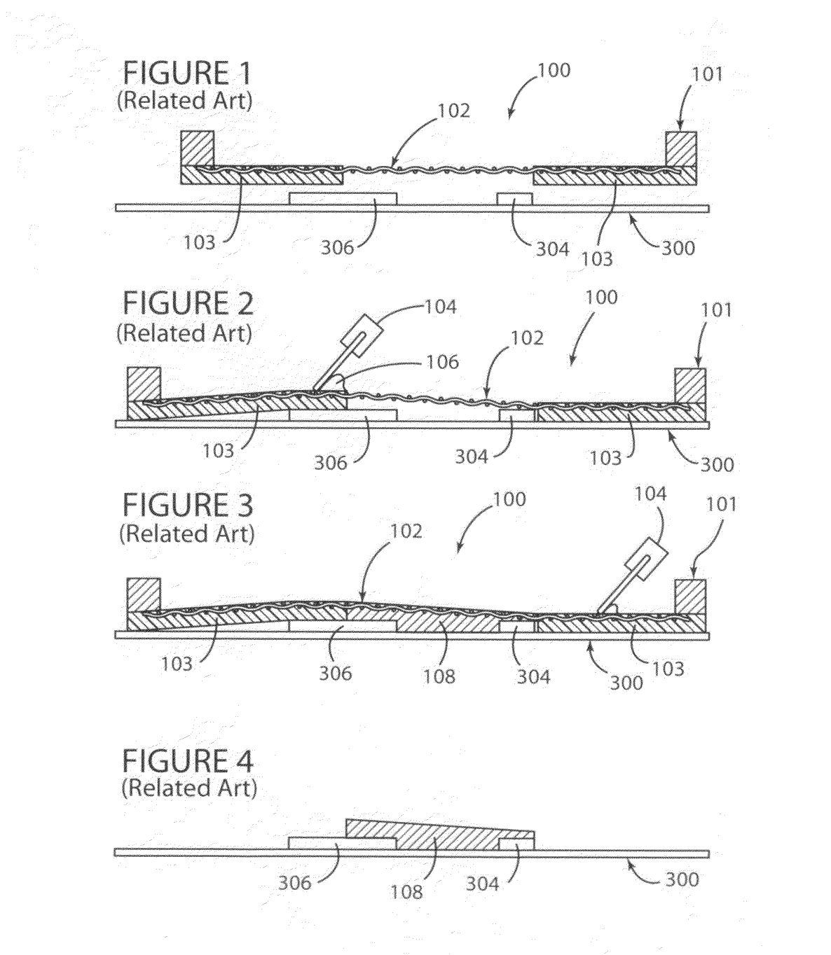

Screen assembly 200 is adapted to be lowered onto or near a printing element or surface such as, for example, the surface 302 of a planar circuit board or substrate 300 as shown in FIGS. 5A, 6, 7, and 8. Substrate 300 can be formed from any suitable material such as ceramic, glass fibers and resin or polyimide. In the embodiment shown, a pair or pattern of raised, spaced-apart, electronic/electrical elements such as, for example, conductors 304 and 306 are seated on top surface 302. Conductors 304 and 306 define electronic/electrical elements which have been either previously placed on the top surface 302 or previously screen printed on the top surface 302 using a screen assembly 100 of the type shown in FIGS. 1-3. Although FIGS. 5-8 show only two conductors 304 and 306 on substrate 300, it is understood that substrate 300 may include several other conductors thereon all together defining a pattern of conductive electronic/electrical elements on the surface 302 of substrate 300.

Resistors or the like electronic/electrical elements 400 are formed on substrate 300 using screen assembly 200 of the present invention as described in more detail below. Initially, and as shown in FIG. 5A, screen assembly 200 is aligned over the substrate 300 in a relationship wherein the positive open mask region 210B overlies the conductor 304 and a portion of the conductor 306, and recess 214 overlies the portion of the conductor 306 which the positive mask region 210B does not overlie.

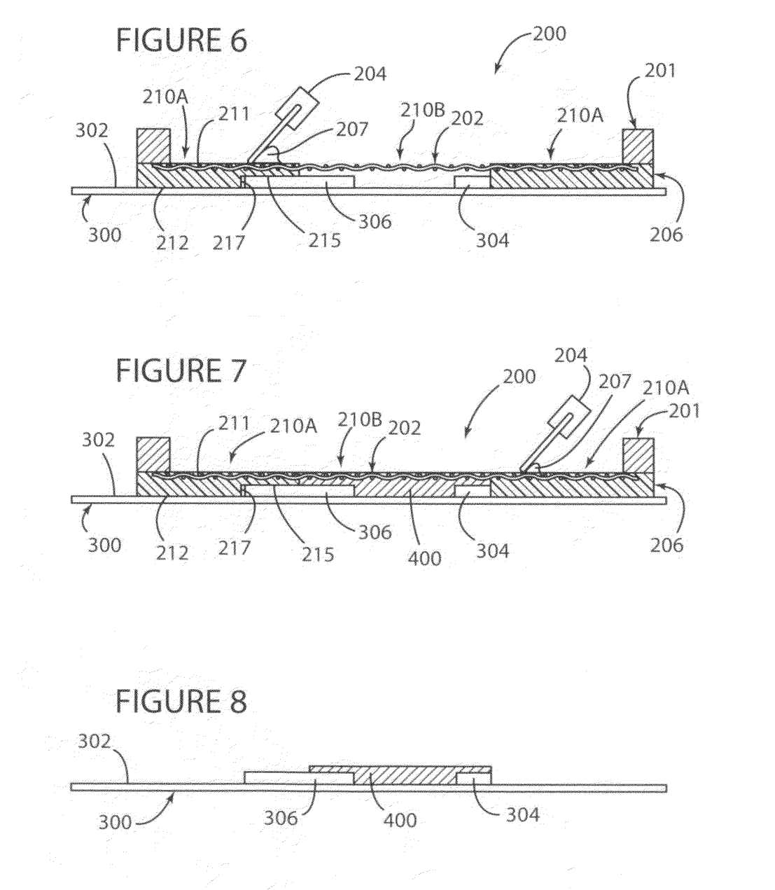

According to the embodiment of the invention as shown in FIGS. 5-8, the recess 214 in screen 202 is sized such that the length thereof is slightly greater than the portion of conductor 306 which the positive mask region 210B does not overly so that the vertical surface 217 defining recess 214 is adjacent to and spaced from the left side edge of conductor 306 in the order of about 2 mils or 0.002 inches. This relationship allows the conductor 306 to be fitted or received in the recess 214 and thus the screen 202 to be positioned and laid flat and horizontal against the top surface 302 of substrate 300 when screen assembly 200 is lowered onto or near the top surface 302 of substrate 300 during printing as shown in FIG. 6.

As shown in FIG. 6, a resistor forming thick film paste 207 is applied to the top surface of screen 202 and a squeegee 204 is slid from left to right as shown in FIGS. 6 and 7 to cause the paste 207 to be wiped over, but not passed through, the negative closed mask pattern regions or areas 210A and extruded or passed downwardly through the positive open mask pattern region or area 210B and then onto the top surface 302 of substrate 300 to form the resistor 400 which, in the embodiment as shown in FIGS. 6 and 7, covers both the portion of the top surface 302 of substrate 300 located between the conductors 304 and 306 and a portion of the top surface of each of the respective conductors 304 and 306 for electrically coupling the two conductors 304 and 306.

As shown in FIG. 8, after the screen assembly 200 is lifted off the substrate 300, the resistor 400 remains on the top surface 302 of substrate 300 and the resistor 400 is subsequently cured in an oven.

Although FIGS. 5-7 depict a screen assembly 200 including only one recess 214 and a substrate 300 including only two conductors 304 and 306, it is understood that the actual number, size, and location of the pattern of one or more recesses formed in the bottom surface of screen 202 will be dependent upon the number, size and location of the pattern of one or more desired resistors to be formed on the surface 302 of substrate 300 and the number, size, and location of the one or more conductors on the surface 302 of substrate 300. For example, it is understood that if the conductor 304 was seated at a location on surface 302 to the right of the location shown in FIGS. 5-8, another recess would have been formed in the bottom surface of the right hand portion of first closed mask region or area 210A, the length of which would be dependent upon the length of the portion of conductor 304 extending beyond the right side edge of second open mask region or area 210B, again for the purpose of assuring that the screen 202 lays flat against the substrate 300 when the screen assembly 200 is lowered onto and seated on the top surface 302 of substrate 300.

It is thus further understood that the present invention encompasses a screen assembly 200 in which a pattern of the one or more recesses or cavities 214, corresponding to and matching the pattern of the one or more conductors 304 and 306 or the like raised elements located on the surface 302 of substrate 300, has been formed, as by etching or the like, in the bottom surface 212 of the layer of emulsion material 206 on screen 202 to assure that, when the screen assembly 200 is lowered onto or near the substrate 300 and the squeegee 204 is slid across the screen 202 during printing, the conductors 304 and 306 are received or fitted in the respective recesses 214 and thus screen 202 lays flat and horizontal against the surface 302 of substrate 300 irrespective of the number, size, or location of the pattern of the one or more conductors 304 and 306 on the surface 302 of substrate 300.

Referring back to the embodiment of FIG. 8, it is still further understood that, by virtue of the presence of the one or more recesses or cavities 214 and the resultant ability to lay the screen 202 flat against the surface 302 of substrate 300 during the printing operation, one or more resistors 400 of uniform and constant thickness, and thus uniform resistance, can be formed on the substrate 300 with minimal pressure (i.e., in the range of only about twelve (12) pounds) being applied to the squeegee 204, thereby also advantageously reducing wear on both the squeegee 204 and screen 202 and thus allowing longer production runs between required screen and/or squeegee changes.

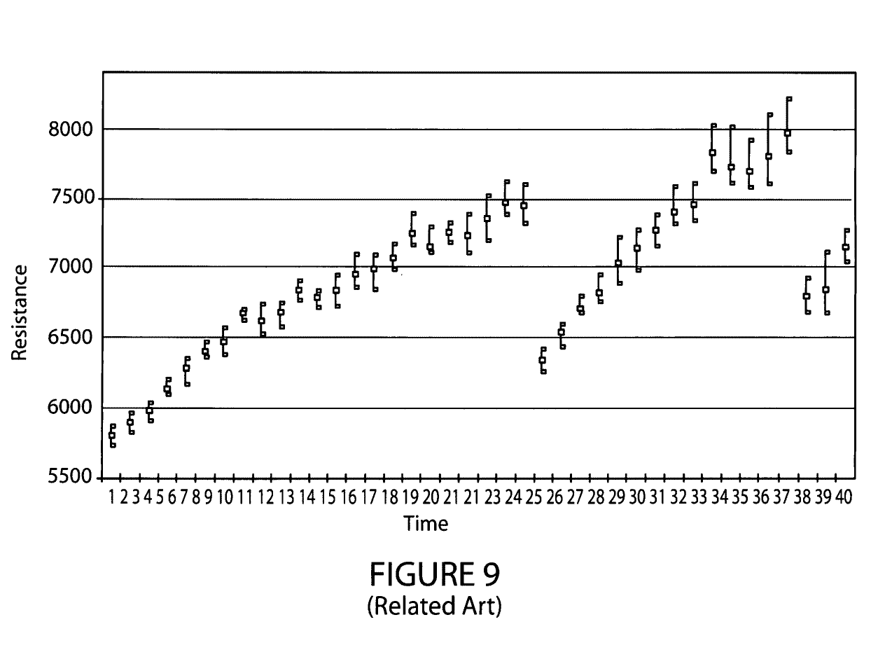

FIG. 9 is a graph of resistor resistance versus production run time/strip number for a resistor 108 of the type shown in FIG. 4 which exhibits that the resistance thereof disadvantageously increases appreciably over time due to the non-uniform thickness of the resistor 108. This of course is very undesirable from a quality and reliability standpoint and may cause resistor 108 to have a resistance value in excess of the maximum allowable or desired limit.

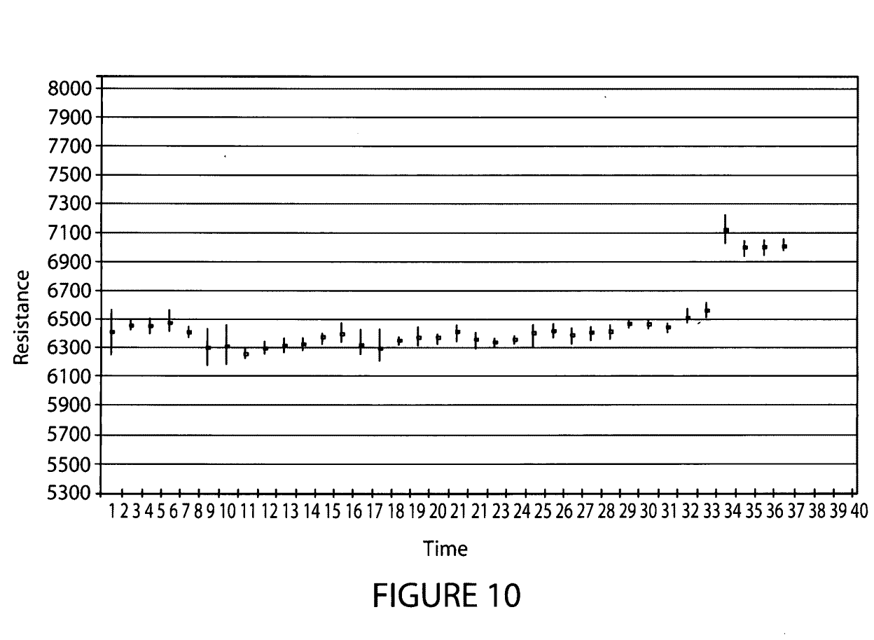

FIG. 10, on the other hand, is a graph of resistor resistance versus production run time/strip number for the resistor 400 formed using the screen assembly 200 of the present invention and exhibits the uniform and constant resistance of resistor 400 over time, i.e., a characteristic which is directly attributable to the uniform and constant thickness of resistor 400 which, in turn, is directly attributable to the presence of recess 214 in screen 202 which, as described above in detail, allows the screen 202 to be laid flat against the surface 302 of the substrate 300 during the printing operation.

Numerous variations and modifications of the embodiment described above may be effected without departing from the spirit and scope of the novel features of the invention. It is to be understood that no limitations with respect to the specific screen assembly illustrated herein are intended or should be inferred. It is, of course, intended to cover by the appended claims all such modifications as fall within the scope of the claims.

I claim:

1. A screen for printing one or more elements on a printing surface including one or more raised elements thereon, the screen comprising:
at least a first region through which a paste cannot pass;
at least a second region through which the paste can pass; and
one or more recesses defined in a bottom portion of said first region of said screen and adapted during printing to receive the one or more respective raised elements on the surface of the printing surface.

2. The screen of claim 1 wherein the screen defines a plurality of openings, the first region comprising a region of the screen in which the plurality of openings have been blocked by a layer of emulsion material and the one or more recesses are defined in a bottom surface of the layer of emulsion material, the second region comprising a region of the screen wherein the paste passes through the plurality of openings.

3. The screen of claim 2 wherein the one or more elements comprise one or more resistors, the thick film resistive paste is made of a material which forms the one or more resistors, the printing surface comprises a substrate, and the one or more raised elements comprise one or more conductors on the surface of the substrate.

4. A screen assembly for printing a pattern of first electrical elements on the surface of a substrate including a pattern of second electrical elements, the screen assembly comprising:
a screen defining a plurality of openings and adapted to be seated on the surface of the substrate;
a layer of material on the screen including respective top and bottom surfaces and blocking the plurality of openings in a first area of the screen; and
a pattern of recesses defined in the bottom surface of the layer of material on the screen matching the pattern of second electrical elements on the surface, of the substrate whereby during printing the pattern of second electrical elements is fitted in the pattern of recesses.

5. The screen assembly of claim 4 wherein a paste made of a resistive thick film material is adapted to pass through the plurality of openings in a second area of the screen, the pattern of first electrical elements comprises a plurality of resistors and the pattern of second electrical elements comprises a plurality of conductors.

6. A screen assembly for printing one or more resistors on the surface of a substrate including one or more raised conductors seated thereon, the screen assembly comprising:
a screen defining a plurality of openings;
at least a first area of the screen being covered with a layer of material which blocks the plurality of openings, the layer of material including a top surface and a bottom surface;
at least a second area of the screen being adapted to allow the passage of a resistor forming paste through the plurality of openings for printing the one or more resistors on the substrate; and
one or more recesses defined in the bottom surface of the layer of material covering the first area of the screen whereby during printing the one or more conductors on the surface of the substrate are fitted in the respective one or more recesses.

7. The screen assembly of claim 6 wherein the recess is located adjacent the second area on the screen.

8. The screen assembly of claim 6 wherein the layer of material is an emulsion material.
